(19) United States
(12) Patent Application Publication
(10) Pub. No.: US 2001/0010893 A1
(43) Pub. Date: Aug. 2, 2001

(54) Negative-working photosensitive resin composition and photosensitive resin plate using the same

(76) Inventors: Hiroshi Takanashi, Tokyo (JP); Tomoya Kudo, Kanagawa-ken (JP)

Correspondence Address: WENDEROTH, LIND & PONACK, L.L.P., 2033 K STREET N. W., SUITE 800, WASHINGTON, DC, 20006-1021, US

(21) Appl. No.: 09/739,750

(22) Filed: Dec. 20, 2000

Related U.S. Application Data
(63) Continuation-in-part of application No. 09/262,077, filed on Mar. 4, 1999.

(30) Foreign Application Priority Data
Mar. 5, 1998 (JP) 10-071513

(51) Int. Cl. G03F 7/029; G03F 7/30

(52) U.S. Cl. 430/281.1; 430/283.1; 430/302; 430/306

(57) ABSTRACT

A negative-working photosensitive resin composition is disclosed, comprising (A) a film-forming polymer, (B) an unsaturated compound having a radical polymerizable ethylenic double bond, (C) a photopolymerization initiator, and (D) a thermal polymerization inhibitor, wherein the resin composition further contains (E) at least one member selected from compounds represented by following formula:

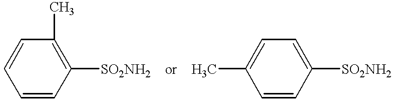

in a range of 3.5 wt % or less based on the weight of the photosensitive resin composition. A photosensitive resin plate using the photosensitive resin composition is also disclosed. By this invention, a negative-working photosensitive resin composition particularly excellent in the reproducibility of the highlight areas and the independent fine lines and having the deep non-printing depth and good resolving properties, and a photosensitive resin plate using the resin composition are provided.

This is a continuation-in-part of Ser. No. 09/262,077, filed Mar. 4, 1999.

### BACKGROUND OF THE INVENTION

1. Field of the Invention

This invention relates to a negative-working photosensitive resin composition utilized for various printing fields and to a photosensitive resin plate using it. More specifically, this invention relates to a negative-working photosensitive resin composition which is excellent in reproducibility of particularly, highlighted areas and independent fine lines, has good depth of non-printing areas (hereinafter, is referred to non-printing depth), and has good resolving properties, and to a photosensitive resin plate using the resin composition.

2. Description of the Related Art

As photosensitive resin compositions used for photosensitive resin plates (printing plates) utilized in the printing fields such as book printing, slip printing, general printing, seal printing, original plates for making mother patterns of seals, flexo printing, dry offset printing, etc., water-soluble, alkali-soluble, or alcohol-soluble negative-working photosensitive resin compositions are known. As the photosensitive resin compositions used for these printing plates, a photosensitive resin composition excellent in reproducibility of highlight areas and independent fine lines and having deep non-printing depth has been desired.

Particularly, recently, with the development of an information-oriented society, the requirements for the improvement of the quality of various prints have been increased. For example, in a photosensitive resin plate used for seal printing, the reproducibility of a highlight of 2-3% at 133 lines/inch (showing that a ratio of the light-transmitting areas to the total area of the light-shielding areas and the light-transmitting areas of a negative film is 2- 3% and that the light-shielding areas are formed by an assembly of dots each having a width of 1/133 inch), and of independent fine lines of a line width of about 10-20 μm has been required. Thus, in the photo-sensitive resin plates used for printing, the improvement of the reproducibility of fine patterns has been more and more desired.

In order to produce such a printing plate having the reproducibility of a highlight and independent fine lines, it is necessary to increase an exposure amount to make a photosensitive resin plate which will sufficiently carry out a photocuring reaction of a photosensitive resin. However, in conventional negative-working photosensitive resin compositions, there are problems such that the exposure latitude (exposure width) is not sufficient, with the increase of the exposure amount, the photocuring reaction at unexposed areas of a photosensitive layer corresponding to light-shielding areas of a negative film proceeds, whereby the depth of non-printing areas and halftone dots areas becomes greatly shallow.

When a photosensitive resin plate having a shallow depth is used as a printing plate, there occurs a problem that the non-printing areas and the halftone dots dark areas are clogged with an ink, whereby areas which should be essentially non-printed can not be reproduced by blackening with an ink, or prints having a dark tone are obtained.

Thus, as an attempt at broadening the exposure width, a photosensitive resin plate having a double-layered photosensitive layer, each layer having a different sensitivity (see JP-A-55-6392 and JP-A-2-970), a photosensitive resin composition containing a compound forming a light-absorptive substance upon light exposure (see JP-A-50-122302), a photosensitive resin plate composed of a photosensitive layer containing N-nitrosodiphenylamine and an adhesive layer containing a Michler's ketone (see JP-A-57-93342), etc., have been proposed.

Also, a photosensitive resin composition containing a compound selected from isoalloxazines and alloxazines and a compound selected from N-nitrosodiphenylamine, N-nitrosocyclohexylhydroxylamine and hydroquinone monomethyl ether (see JP-A-3-2757), a photosensitive resin composition obtained by adding an azo dye to a photosensitive composition using a styrene-butadiene block copolymer, etc. (see JP-A-5-273752), a method of improving transparency of a photosensitive layer by heat treating a photosensitive composition containing a crystalline polymer at a temperature of 40-120° C. (see JP-A-59-123836), etc., have been proposed.

A negative-working photosensitive resin composition typically comprises a combination of a film-forming polymer, a radical polymerizable unsaturated compound, and a photopolymerization initiator, and where it sometimes happens that by an oozing phenomenon of the unsaturated compound from the photosensitive resin composition, the surface of a photosensitive layer, which is formed by the photosensitive composition, becomes tacky and thus, as the case may be, there occurs a problem that in intimate contact of a negative film (mask pattern) with the surface of the photosensitive layer at exposure, by the influence of air confined between the negative film and the photosensitive layer, images (photocured patterns) become indistinct, and also, the halftone dots depth and the non-printing area depth become shallow.

In view of the fact that the reproduction of fine patterns relates to the state of intimate contact of a negative film with the surface of a photosensitive layer at exposure as described above, an attempt of improving the reproducibility of fine patterns by improving surface properties of a photosensitive layer is reported, and, for example, a sticking prevention method by matting the surface of a photosensitive layer (see JP-A-50-31488, JP-A-63-146045, JP-A-5-313356, etc.), a slip coating method for sticking prevention by leaving a resin, which is hard to stick to a negative film, on the surface of a photosensitive layer (see JP-A-5-232708, JP-A5-27419, JP-A-4-359256, JP-A-51-49803, JP-A-58-18633, JP-A-57-34557, JP-A-9-71765, JP-A-5-297594, etc.), etc., are proposed.

Also, an attempt of a three-layered mat cover, etc., is reported (JP-A-63-259552).

In U.S. Pat. No. 4,361,640, there are disclosed photopolymerizable compositions optionally containing mixed o,p-toluenesulfonamides in an amount of 0 to 18 wt % and preferably 6 to 15 wt % Morever, in JP (KOKAI) 11-249291 there are disclosed photopolymerizable compositions containing certain substituted toluenesulfonamides in small amounts.

However, in the present printing industry, a higher quality is being demanded, and negative-working photosensitive resin compositions sufficiently meeting these requirements have not yet been realized.

As a result of various investigations, it has been discovered that the above-described problems can be solved by incorporating a specific amount of o- or p-toluenesulfonamide in a radical polymerization-type negative-working photosensitive resin composition and, particularly, that a photosensitive resin plate having a deep non-printing depth can be obtained even by increasing the exposure amount, leading to accomplishment of this invention.

### SUMMARY OF THE INVENTION

This invention has been made in view of the above-described circumstances. Thus, an object of this invention is to provide a negative-working photosensitive resin composition which is excellent in reproducibility of highlight areas and independent fine lines having a line width of about 10-20 μm, does not make the non-printing depth shallow even by increasing the exposure amount on plate making, and has an improved exposure width, as well as a photosensitive resin plate using the resin composition.

That is, this invention provides a negative-working photosensitive resin composition comprising (A) a film-forming polymer, (B) an unsaturated compound having a radical polymerizable ethylenic double bond, (C) a photopolymerization initiator, and (D) a thermal polymerization inhibitor, wherein the resin composition further contains (E) at least one compound represented by the following formulae:

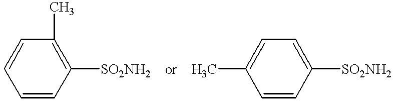

in an amount of 3.5 wt % or less based on the weight of the photosensitive resin composition.

Also, this invention provides a photosensitive resin plate (raw plate or to-be-exposed plate) comprising a support having thereon a photosensitive layer comprising the above-described negative working photosensitive resin composition directly or via an adhesive layer.

Furthermore, this invention provides a photosensitive resin plate having formed thereon photocured images obtained by selectively exposing the photosensitive layer on the above-described photosensitive resin plate through a mask pattern, developing, and forming the photocured images by removing the unexposed areas.

### DETAILED DESCRIPTION OF THE INVENTION

The negative-working photosensitive resin composition of this invention and the photosensitive resin plate using it are hereunder described in detail.

As the film-forming polymer (A), water-soluble polymers, alkali-soluble polymers, and alcohol-soluble polymers are preferably used.

(A-1) Water-soluble polymer

As the water-soluble polymer used in this invention, any polymers which are dissolved in ordinary water having a pH of from about 5 to 8 can be used without specific restrictions. Specific examples include polyvinyl alcohol, N-methylolacryl-amide-added polyvinyl alcohol, denatured polyvinyl alcohols (such as a polyvinyl alcohol/polyacrylate block copolymer, denatured polyvinyl alcohol having acrylic anhydride reacted therewith, and grafted polyvinyl alcohol), carboxyalkyl celluloses, polyamides having a sodium sulfonate group, a polyamide having an ether bond, a polyamide having basic nitrogen or ammonium salt-type nitrogen, and polyvinyl pyrrolidone, but the water-soluble polymer used in this invention is not limited to these polymers. Among these polymers, polyvinyl alcohol is suitably used because it is relatively inexpensive. The water-soluble polymers may be used singly or as a combination of two or more thereof.

(A-2) Alkali-soluble polymer

As the alkali-soluble polymer used in this invention, polymers which are dissolved or dispersed in an aqueous alkaline solution having a pH of about 8 or higher can be used without particular restrictions, and examples include polymers having a group such as —COOH, —PO₃H₂, —SO₃H, —SO₂NH₂ —SO₂NHSO₂—, and SO₂NH—CO—.

Specific examples of the polymer include maleic anhydride-denatured polybutadiene, a carboxyl group-containing styrene-butadiene copolymer, a maleic ester resin, a polymer of B-methacryloyloxyethyl-N-(p-trisulfonyl)carbamate, copolymers of monomers similar to the monomers constituting these polymers and other monomers, a vinyl acetate/crotonic acid copolymer, a styrene/maleic anhydride copolymer, a methacrylic ester/methacrylic acid copolymer, a methacrylic acid/styrene/acrylonitrile copolymer, and cellulose acetate phthalate, but the alkali-soluble polymers used in this invention are not limited to these polymers. Among these polymers, cellulose acetate phthalate is preferably used in view of transparency and solubility. The alkali-soluble polymers maybe used singly or as a combination of two or more thereof.

(A-3) Alcohol-soluble polymer

As the alcohol-soluble polymer used in this invention, alcohol-soluble nylons are preferred. Specific examples include 8 nylon, 6 nylon/66 nylon, 6 nylon/66 nylon/610 nylon, 6 nylon/66 nylon/610 nylon/612 nylon, and a 4,4′-diaminodicyclohexylmethane/hexamethylenediamine/adipic acid/ε-caprolactam copolymer, but the invention is not limited to these polymers. Among these polymers, 8 nylon and 4,4′-diaminodicyclohexylmethane/hexamethylenediamine/adipic acid/ε-caprolactam copolymer are preferably used in view of transparency and solubility. The alcohol-soluble polymers may be used singly or as a combination of two or more thereof.

The content of the component (A) is preferably 15-70 wt %, more preferably 20-65 wt %, and particularly preferably 25-60 wt % of the total solid components of the photosensitive resin composition of this invention. If the content exceeds the above-described range, a problem in that the facility of washing out unexposed areas is lowered, the photocuring reaction of exposed areas does not sufficiently proceed, etc. On the other hand, if the content is less than the above-described range, there is a tendency that a cold flow phenomenon in which at high temperatures the photosensitive resin plate is deformed and does not reflect a raw plate's form, i.e., a to-be-exposed photosensitive resin plate's form.

As the unsaturated compound (B) having a radical polymerizable ethylenic double bond, unsaturated compounds generally used for photosensitive resin compositions can be used without particular restrictions. Specific examples include ethylene glycolmono(meth)acrylate, diethylene glycol mono(meth)acrylate, propylene glycol mono(meth)acrylate, polyethylene glycol mono(meth)acrylate, polypropylene glycol mono(meth)acrylate, polyethylene glycol monomethoxymonoacrylate, N-methylolacrylamide, N-ethylolacrylamide, N-propylolacrylamide, N-methylol(meth)acrylamide, N-ethylol(meth)acrylamide, N-propylolmethacrylamide, diacetoneacrylamide, hydroxypropyl acrylate, triacrylformal, diacrylamide dimethylene ether, methylene bisacrylamide, ethylene glycol di(meth)acrylate, diethylene glycol di(meth)acrylate, triethylene glycol di(meth)acrylate, tetraethylene glycol di(meth)acrylate, polyethylene glycol di(meth)acrylate, trimethylolpropane tri(meth)acrylate, trimethylolpropane di(meth)acrylate, oligourethane di(meth)acrylate, 1,3-butanediol di(meth)acrylate, 1,4-butanediol di(meth)acrylate, 1,6-hexanediol di(meth)acrylate, pentaerythritol tetra(meth)acrylate, pentaerythritol tri(meth)acrylate, triacrylformal, and an adduct of a bisepoxy compound and acrylic acid. The unsaturated compounds having a radical polymerizable ethylenic double bond may be used singly or as a combination of two or more thereof.

The content of the component (B) is preferably 20-50 wt %, and more preferably 25-45 wt % of the total solid components of the photosensitive resin composition of this invention. If the component exceeds the above-described range, there is a tendency that the compound causes phase separation and oozes during storing the photosensitive resin plate. On the other hand, if the content is less than the above-described range, there is a tendency of lowering the reproducibility of images.

As the photopolymerization initiator (C), there are no particular restrictions, and conventionally known ones can be optionally used. Specific examples include benzophenone derivatives such as benzophenone and 2-hydroxy-4-alkoxybenzophenone; benzoin derivatives such as benzoin, benzoin isopropyl ether, benzoin methyl ether, benzoin ethyl ether, and benzoin isobutyl ether; xanthone derivatives such as xanthone, thioxanthone, and 2-ethylthioxanthone; anthraquinone derivatives such as anthraquinone, methylanthraquinone, ethylanthraquinone, carboxyanthraquinone, sodium 2,6-anthraquinonedisulfonate, and sodium 2,7-anthraquinonedisulfonate; benzyl dimethyl ketal; acetophenone; and 2,2-diethoxyacetophenone, but the component (C) used in this invention is not limited to these compounds. The photopolymerization initiators may be used singly or as a combination of two or more thereof.

The content of the component (C) is preferably 0.5- 5 wt %, and more preferably 1-4 wt % of the total solid components of the photosensitive resin composition of this invention. If the content exceeds the above-described range, a problem that the increase of the ultraviolet absorption by the component (C) itself makes the photocuring reaction in a lower portion of the image not sufficiently proceed is liable to occur. On the other hand, if the content thereof is less than the above-described range, there is a tendency that the reproducibility of the fine lines and independent dots is deteriorated.

The thermal polymerization inhibitor (D) is used for not only restraining the occurrence of the polymerization reaction of the composition during stirring under heating but also improving the storage stability of photosensitive resin plates after the production. There are no particular restrictions on the thermal polymerization inhibitor and conventionally known ones can be optionally used. Specific examples include quinone derivatives such as hydroquinone, methylhydroquinone, and p-benzoquinone; phenol derivatives such as 2,6-di-tert-butyl-p-cresol; and nitrobenzene or derivatives thereof, but the component (D) used in this invention is not limited to these compounds. The thermal polymerization inhibitors may be used singly or as a combination of two or more thereof.

The content of the component (D) is preferably 0.01- 1 wt % of the total solid components of the photosensitive resin composition of this invention. If the content exceeds the above-described range, a problem of lowering the sensitivity at using the photosensitive resin plate is liable to occur. On the other hand, if the content is less than the above-described range, there is a tendency that the restraint of the polymerization reaction and the storage stability are deteriorated.

In this invention, in addition to the above-described components (A) to (D), it is necessary that (E) at least one compound represented by the following formulae:

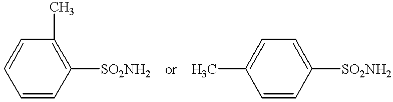

be contained in the photosensitive resin composition in a range of 3.5 wt % or less, preferably 0.5-2.0 wt %, and more preferably 1.0- 1.5 wt %, based on the weight of the photosensitive composition.

In general, in the production of a printing plate using a radical polymerization-type negative-working photosensitive resin composition, the depth and resolution of the image (relief) are strongly influenced by oxygen upon the irradiation of light and are determined by the balance of the diffusing amount of oxygen retained between the surface of a photosensitive layer comprising a photosensitive resin composition formed on a support and a negative film (mask pattern) into the photosensitive layer, and the radical generating amount in the inside of the photosensitive layer.

Because oxygen diffused into the photosensitive layer acts as a radical polymerization inhibitor to show a desensitizing action, when the amount of oxygen retained between the negative film and the surface of the photosensitive layer is small, the desensitizing action by oxygen is small, and the non-printing depth becomes shallow. On the other hand, if the amount of oxygen is high, the sensitivity is lowered, and the form of the image areas is deteriorated.

Accordingly, in order to improve the non-printing depth without lowering the sensitivity, it is necessary to properly control the oxygen between the negative film and the surface of the photosensitive layer in the photosensitive layer.

On the other hand, it is known by experience that in the negative-working photosensitive resin plate using a film-forming polymer soluble in an alcohol, water, or an aqueous alkaline solution, when about 3 to 7 days passes after the production, the “Step Tablet” (Eastman Kodak Corporation) sensitivity increases by from 1 to 2 steps. This is considered to be caused by the fact that by forming a three-dimensional network structure of hydrogen bonds by the polar groups in the components (A) and (B) in the photosensitive resin composition, that is, by crystallization, the diffusion of oxygen into the photosensitive layer at the irradiation of light is prevented, and the desensitizing action by oxygen is restrained.

In this invention, it is considered that by incorporating the above-described specific amount of the component (E) in the photosensitive resin composition, not only the three-dimensional network structure by the hydrogen bonds in the photosensitive resin composition is destroyed, but also the diffusing amount of oxygen into the photosensitive layer can be properly controlled. Thus, the radical generating amount and the diffusing amount of oxygen at the irradiation of light can be balanced well, and the negative-working photosensitive resin composition excellent in the reproducibility of the highlight areas and the fine patters of independent fine lines, particularly having a deep non-printing depth even by increasing the exposure amount at plate making and having an improved exposure width, is realized.

As the reason for this, it is considered that the compound represented by the formula

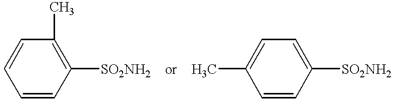

has only one polar group (—SO₂NH₂) in the structure, and the one polar group —SO₂NH₂ approaches the hydrogen bond portion of the photosensitive resin composition, and by incorporation of non-polar portions of the compound into the hydrogen-bonded portion of the resin composition, the hydrogen bond in the photosensitive resin composition is hindered to destroy the network structure, whereby oxygen becomes liable to diffuse. Also, it is considered that oxygen diffused in the resin traps radicals generated by the irradiation of light upon exposure, whereby the occurrence of the polymerization reaction on the surface of the photosensitive layer is restrained, and lowering the non-printing depth is restrained even by increasing the exposure amount.

It is necessary that only one polar group (—SO₂NH₂) exist in the compound. If two or more polar groups exist in the compound, they supplement the network structure by the hydrogen bonds in the photosensitive resin composition, whereby not only the effect of destroying the network structure, but also the non-printing depth is made shallow.

The content of the component (E) is 3.5 wt % or less, and preferably 0.5-2.0 and more preferably 1.0 to 1.5 wt % based on the weight of the photosensitive resin composition.

When component (E) has high compatibility with the photosensitive resin composition, if its content exceeds the above-described range, the component (E) elutes out from the photocured areas (imaged areas) upon washing out (development) of the unexposed areas, and also, the strength of the photocured areas is lowered, whereby the photocured areas are scratched on washing out using a brush, and the halftone dots and fine lines are broken. Also, in spray development, because a brush is not used for washing out, although the photocured areas are not scratched, by elution of the component (E) from the photocured areas, the film at the halftone highlight and the fine lines are reduced, and the photosensitive resin plate is inferior as a printing plate material.

On the other hand, when the component (E) has low compatibility with the photosensitive resin composition, if its content exceeds the above-described range, the component (E) is separated from the photosensitive layer and is deposited before exposure, the photosensitive layer becomes opaque to cause scattering of light, and the non-printing depth is made shallow.

Also, because the compounding amount of the compound (E) is slight, phenomena of transferring the component (E) onto the surface of the photosensitive layer and of rising of the component (E) on the surface are not observed.

By the addition of component (E), the above-mentioned advantageous effects of this invention are obtained. Furthermore, it shall be specifically noted that a defect in the conventional technology that in winter (a dry season), a photosensitive resin plate using a polar polymer such as polyvinyl alcohol, is liable to be cracked can be improved. It is considered that such an advantageous effect is obtained by destroying the network structure by the hydrogen bonds in the resin by the addition of the component (E).

To the negative-working photosensitive resin composition of this invention, if necessary, other additives can be further added. As one of these additives, plasticizers can be used. While there are no particular restrictions on the plasticizers, examples thereof include a compound having a hydroxyl group, such as trimethylolpropane, glycerol, ethylene glycol, diethylene glycol, triethylene glycol, tetraethylene glycol, polyethylene glycol, and propylene glycol. Also, by adding a surfactant, a dye, etc., negative-working photosensitive resin compositions having various functions can be obtained.

The photosensitive resin plate of this invention can be prepared using the photosensitive resin composition of this invention by, for example, the following.

That is, the component (A) is first dissolved in a solvent and the components (B) to (E) and other optional additives are added to the solution in an arbitrary order, followed by mixing to provide a photosensitive resin composition liquid.

The photosensitive resin composition liquid is coated on a cover film such as a polyethylene terephthalate film by a coating apparatus such as a curtain coater, a doctor blade coater, a reverse coater, etc., and dried to form a photosensitive layer of from 0.45 to 0.8 mm in thickness.

On the other hand, an adhesive layer is formed on a film base (support) such as a polyester film and heat-treated with a hot plate, etc., to make the adhesive layer in a semi-cured state.

Then, by press-attaching the photosensitive layer on the adhesive layer in a semi-cured state, a photosensitive resin plate (raw plate or to-be-exposed plate) of this invention is produced.

For the adhesive layer, a conventionally known adhesive such as a polyester-based adhesive and an epoxy-based adhesive can be used. Also, the photosensitive layer may be directly formed on a support without using an adhesive layer.

A photocured image-forming process on the photosensitive resin plate (raw plate or to-be-exposed plate) thus obtained can be carried out by an ordinary method, and depending upon the photosensitive resin composition used, the development conditions, the exposure conditions, etc., can be properly changed. Specifically, for example, after releasing the cover film from the surface of the photosensitive layer, the photosensitive layer is exposed through a negative mask using a chemical lamp of an output of about 10-50 W from a distance of 25-50 mm for about 2-15 minutes. Then, the unexposed areas are removed by washing out with a solvent capable of dissolving the unexposed areas using a brush, etc., and the photosensitive layer is then dried at a temperature of 70-90° C. for about 2-10 minutes. Thereafter, if desired, a post exposure is applied for about 5-10 minutes by using the above-described chemical lamp, whereby a photosensitive resin plate having photocured images formed thereon can be obtained.

By using known techniques such as matting of the photosensitive layer, the formation of a slip coat on the surface of the photosensitive layer, or the formation of a sticking prevention layer, etc., together with the technique of this invention, the effects of these known techniques can be effectively obtained in addition to the above-described characteristic effects of this invention.

### EXAMPLES

This invention is described specifically by the following Examples, but this invention is not limited to these Examples.

The following Examples demonstrate that unexpected results of the present invention are exhibited in the claimed range of 3.5 wt % or less of component (E), whereas the said effects are not exhibited when component (E) is added in the amount of 4-18 wt %. The preferred range of mixed o,p-toluenesulfonamide is 6-15 wt % as disclosed in Pine (U.S. Pat. No. 4,361,640).

### [0056] EXAMPLES 1 - 17

(i) Preparation of water-soluble photosensitive resin compositions 1-17

In 200 parts by weight of water was dissolved 200 parts by weight of polyvinyl alcohol (degree of saponification: 70%, degree of polymerization: 500) as component (A), and then 70 parts by weight of polyethylene glycol diacrylate as component (B), 4 parts by weight of benzyldimethyl ketal as component (C), 0.1 part by weight of methylhydroquinone as component (D), and X parts by weight (X: addition amount indicated in Table I below) of p-toluenesulfonamide were added as component (E) to the solution to prepare water-soluble photosensitive resin compositions 1-17.

(ii) Production of photosensitive resin plates 1-17

Each of the above-described water-soluble photosensitive resin compositions 1-17 was coated onto a polyester film (cover film), followed by drying to form a photosensitive layer of 0.7 mm in thickness. Then, a base was adhered thereto to provide photosensitive resin plates (raw plates or to-be-exposed plates) 1-17 each. [0058] (iii) Evaluation of Depth of Non-printing area

After each of the cover film was released from the photosensitive resin plates 1-17, the photosensitive resin plates 1-17 were exposed through a mask having independent fine lines of 150 μm, using a chemical lamp of 20 W from a distance of 45 mm for 10 minutes, and then, the unexposed areas were removed by washing out with water of 35° C. using a brush, followed by drying at 80° C. for 5 minutes to make printing plates.

The depth was evaluated by the depth (μm) of non-printing areas of independent fine lines of 150 μm of the printing plates. The results are shown in Table I.

### [0060] EXAMPLES 18-34

By following the same procedures as Examples 1- 17 above, except that o-toluenesulfonamide was used instead of p-toluenesulfonamide, water-soluble photosensitive resin compositions 18-34 were prepared, and photosensitive resin plates 18-34 were obtained.

Using the plates 18-34, the depth was evaluated in the same manner as described in Examples 1-17 above. The results are shown in Table I.

TABLE I

| | | Addition | |
|---|---|---|---|
| | | Amount of | Depth |
| | Component (E) | Component (E) | (μm) |
| Example 1 | p-toluenesulfonamide | 0 | 30 |
| Example 2 | p-toluenesulfonamide | 0.047 | 31 |
| Example 3 | p-toluenesulfonamide | 0.1 | 32 |
| Example 4 | p-toluenesulfonamide | 0.2 | 33 |
| Example 5 | p-toluenesulfonamide | 0.3 | 38 |
| Example 6 | p-toluenesulfonamide | 0.5 | 60 |
| Example 7 | p-toluenesulfonamide | 1.0 | 80 |
| Example 8 | p-toluenesulfonamide | 1.25 | 82 |
| Example 9 | p-toluenesulfonamide | 1.50 | 78 |
| Example 10 | p-toluenesulfonamide | 2.0 | 64 |
| Example 11 | p-toluenesulfonamide | 3.0 | 42.5 |
| Example 12 | p-toluenesulfonamide | 3.50 | 34 |
| Example 13 | p-toluenesulfonamide | 4.0 | 28 |
| Example 14 | p-toluenesulfonamide | 5.0 | 22 |
| Example 15 | p-toluenesulfonamide | 10.0 | 23 |
| Example 16 | p-toluenesulfonamide | 15.0 | 25.5 |
| Example 17 | p-toluenesulfonamide | 18.0 | 28 |
| Example 18 | o-toluenesulfonamide | 0 | 30 |
| Example 19 | o-toluenesulfonamide | 0.047 | 32 |
| Example 20 | o-toluenesulfonamide | 0.1 | 33 |
| Example 21 | o-toluenesulfonamide | 0.2 | 33 |
| Example 22 | o-toluenesulfonamide | 0.3 | 38 |
| Example 23 | o-toluenesulfonamide | 0.5 | 39 |
| Example 24 | o-toluenesulfonamide | 1.0 | 43 |
| Example 25 | o-toluenesulfonamide | 1.25 | 46 |
| Example 26 | o-toluenesulfonamide | 1.50 | 49 |
| Example 27 | o-toluenesulfonamide | 2.0 | 48 |
| Example 28 | o-toluenesulfonamide | 3.0 | 37 |
| Example 29 | o-toluenesulfonamide | 3.50 | 34 |
| Example 30 | o-toluenesulfonamide | 4.0 | 28 |
| Example 31 | o-toluenesulfonamide | 5.0 | 24 |
| Example 32 | o-toluenesulfonamide | 10.0 | 22 |
| Example 33 | o-toluenesulfonamide | 15.0 | 20 |
| Example 34 | o-toluenesulfonamide | 18.0 | 21 |

As shown in Table I above, it is verified that remarkable effects of the invention of deep depth of non-printing areas and excellent resolving properties were exhibited in the claimed range of 3.5 wt % or less of component (E) of the present invention, whereas the said effects could not be exhibited when component (E) was added in the amount of 4-18 wt %. The preferred range of mixed o,p-toluenesulfonamide, disclosed in Pine (U.S. Pat. No. 4,361,640), is 6-18 wt %.

As described above in detail, according to this invention, a water-soluble, alkali-soluble or alcohol-soluble negative-working photosensitive resin composition which is useful for producing a photosensitive resin plate for printing utilized for various printing fields is obtained. Also, by using the resin composition, the production of a photosensitive resin plate, which is excellent in the reproducibility of the highlight areas and the independent fine lines, has a deep non-printing depth, and has good resolving properties, becomes possible.

What is claimed is:

1. A negative-working photosensitive composition comprising:
(A) a film-forming polymer
(B) an unsaturated compound having a radical polymerizable ethylenic double bond,
(C) a photopolymerization initiator,
(D) a thermal polymerization inhibitor, and
(E) at least one member selected from compounds represented by the following formula: 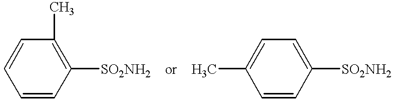
in an amount of 3.5 wt % or less based on the weight of the photosensitive resin composition.

2. The negative-working photosensitive resin composition according to claim 1, wherein the amount of component (E) is in the range of 0.5-2.0 wt % based on the weight of the photosensitive resin composition.

3. The negative-working photosensitive resin composition according to claim 1, wherein the amount of component (E) is in the range of 1.0-1.5 wt % based on the weight of the photosensitive resin composition.

4. The negative-working photosensitive resin composition according to claim 1, wherein component (E) is p-toluenesulfonamide.

5. The negative-working photosensitive resin composition according to claim 1, wherein component (A) is a water-soluble polymer.
